(19) United States
(12) Patent Application Publication
(10) Pub. No.: US 2005/0186690 A1
(43) Pub. Date: Aug. 25, 2005

(54) Method for improving semiconductor wafer test accuracy

(75) Inventors: Hui-Mei Chen, Hsin-chu City (TW); Chien-Kang Chou, Shin Wha Town (TW); Jin-Yuan Lee, Hsin-Chu City (TW); Hsien-Tsung Liu, Hsin-Chu City (TW)

Correspondence Address: GEORGE O. SAILE, 28 DAVIS AVENUE, POUGHKEEPSIE, NY, 12603, US

(73) Assignee: Megic Corporation

(21) Appl. No.: 10/786,807

(22) Filed: Feb. 25, 2004

(51) Int. Cl. H01L 21/66

(52) U.S. Cl. 438/14; 438/17

(57) ABSTRACT

A method for improving the accuracy of electrical test results of semiconductor wafers is described. The method introduces a non-contacting physical cleaning process prior to testing. The cleaning process removes micro-contamination on circuit contact pads that has been introduced during semiconductor wafer processing. This results in more accurate electrical probing of the semiconductor wafers.

### FIELD OF THE INVENTION

This invention relates in general to the methods of testing of semiconductor wafers in particular to the processes prior to final wafer testing.

### BACKGROUND OF THE INVENTION

The following three U.S. patents relate to the methods of testing of semiconductor wafers.

U.S. Pat. No. 6,291,268B1 dated Sep. 18, 2001, issued to C. W. Ho shows a method for testing a BGA substrate.

U.S. Pat. No. 6,162,652 dated Dec. 19, 2000, issued to M. L. A. Dass et. al. describes a method of cleaning and testing bumped wafers.

U.S. Pat. No. 6,143,668 dated Nov. 7, 2000, issued to M. L. A. Dass et. al. describes a wafer testing method utilizing cleaning of bond pads prior to testing.

The manufacture of electrical circuits on semiconductor wafers incorporates testing the circuits at several stages of the fabrication process. Final testing at the wafer level is usually the most important as it affects the yield of the process and any additional cost of further processing defective product.

The usual method of wafer testing utilizes probes that contact the metal surface pads of a wafer. These surface pads are connected to the semiconductor circuits. The probes in turn are connected to highly sophisticated test circuitry that provides electrical signals to the circuits and analyzes their response. The design of the contact probes, both electrical and mechanical, has been the topic of many studies since the invention of integrated circuits.

The accuracy of the final test process is highly important. Methods for addressing this problem have resulted in many different wafer test systems and test probe designs, as well as methods of testing.

Particular attention has been paid to the interface between the test probes and the surface metal pads of the wafers. The electrical parameters of the contact can affect the results of the testing. Specifically, the electrical resistance of the contact is of the first order.

The metallurgy of the contact pads, aluminum Al, gold Au, lead Pb, or their alloys, determines the force required to provide an acceptable contact. Surface contamination on the circuit pads also affects the necessary force of the probes.

All of these variables, if not properly addressed, result in false indications of defective circuits during electrical testing of the semiconductor wafers.

### SUMMARY OF THE INVENTION

It is an object of the present invention to provide a process whereby the accuracy of wafer testing is increased.

It is also an object of the present invention that the process utilizes current semiconductor wafer fabrication processes.

It is a further of the present invention that the process is applicable to surface contact pads as well as metal bumped wafers.

The above objectives are achieved by one or more embodiments of the present invention by providing a circuit pad or bump cleaning process prior to final testing of the semiconductor wafers.

FIG. 1 shows a cross-section of a typical metal circuit pad on a semiconductor wafer. The semiconductor wafer 10 with interconnecting metal 12, pad metal 14 and a passivation layer 16 usually has micro-contamination 18 absorbed on the surface of the metal pad 14. This contamination is usually introduced during wafer processing.

A physical cleaning process is introduced that does not contact the wafer surface pads. The physical cleaning process may be a sputter-etch process, or an ion milling process.

The results of the said cleaning process are shown in FIG. 2 wherein the micro-contamination on the surface of the circuit pads has been removed. The circuit pads without the micro-contamination will not affect the wafer test results when probed.

### BRIEF DESCRIPTION OF THE DRAWINGS

The present invention will be more clearly understood from the following description with the accompanying drawing in which like reference numerals designate similar or corresponding elements, regions, and portions and in which:

FIG. 1 is a cross-sectional view of a contaminated circuit pad.

FIG. 2 is a cross-sectional view of a clean circuit pad.

FIG. 3 is a cross-sectional view of a contaminated circuit pad being probed.

FIG. 4 is a cross-sectional view of a contaminated circuit pad and testing probe after probing.

FIG. 5 is a cross-sectional view of a contaminated circuit pad being probed by a contaminated probe.

FIG. 6 is a cross-sectional view of a circuit pad with a contact metal bump being probed.

FIG. 7 is a cross-sectional view of a circuit pad with a contaminated metal bump after probing.

FIG. 8 is a cross-sectional view of a circuit pad with a contaminated metal bump being probed by a contaminated probe.

FIG. 9 is a cross-sectional view with bump metal after the cleaning process.

### DETAILED DESCRIPTION OF THE PREFERRED EMBODIMENT

The demands of highly effective semiconductor wafer testing methods have resulted in efficient wafer testing systems that utilize wafer probe stations. The wafer probe stations have been designed to test the VLSI circuits used in today's semiconductor wafers. In addition, the wafer probes have been designed to interface with the different materials used in the semiconductor wafer circuit pads. Gold Au, lead Pb, and their alloys are currently used as circuit pads on semiconductor wafers. In addition, metal bumps may be present for future use as package interconnects.

The metallurgy and the shape of the circuit pads are variable that need to be addressed in test probe design. The condition of the micro surface of the circuit pads or bumps is also of first order importance in obtaining the correct electrical test results. The test results are used to determine the acceptability of the semiconductor chips on the semiconductor wafer, and determine the process of product yield.

The first embodiment of the present invention addresses the problem of surface micro-contamination on the circuit pads of semiconductor wafers as shown in FIG. 1. A semiconductor wafer 10 with interconnecting metal 12, metal pad 14, and a passivation layer 16 has the surface of the metal pad 14 micro-contaminated 18 during fabrication. The semiconductor wafer FIG. 1 is tested by contacting the contaminated metal pad 14, 18 with a probe 20 as shown in FIG. 3.

The probe 20 after testing has micro-contamination 22 adhering to the tip end. Testing of another semiconductor wafer utilizing the same probe station results in a micro-contaminated probe 20, 22 to come in contact with a micro-contaminated circuit pad 14, 18 of the new semiconductor wafer.

The results of the above process are erroneous test readings, such as a false open circuit indication due to the high electrical resistance of the contaminated probe contact.

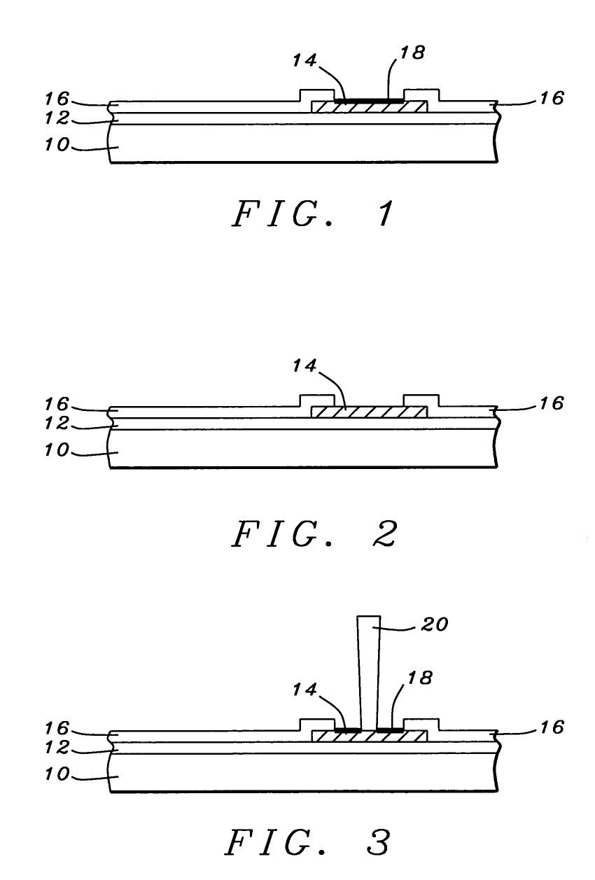

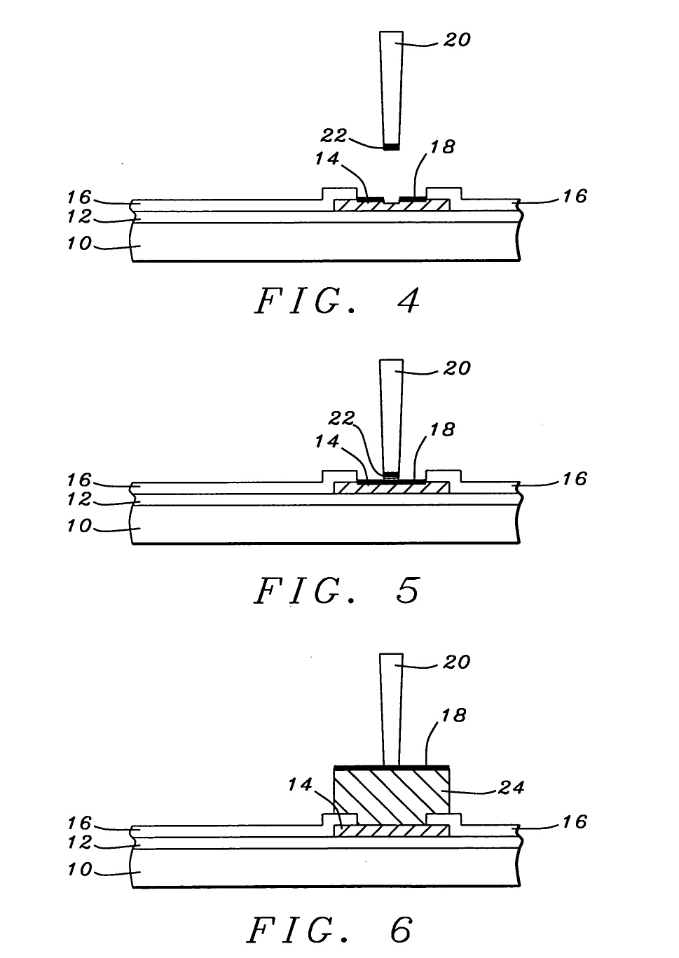

The first embodiment of the present invention is the introduction of a non-contacting physical cleaning process. The process utilizes an inert gas such as argon Ar, helium He, or neon Ne in a sputtering or ion milling method to totally remove the micro-contaminants from the circuit pad surface as shown in FIG. 2. This allows for a non-resistive electrical contact during wafer testing which in turn does not produce false indications of defective product.

The second embodiment of the present invention addresses the problem of micro-contamination on semiconductor wafer circuit pads with metal bumps as shown in FIG. 6. A semiconductor wafer 10 with interconnect metallurgy 12, a passivation layer 16, circuit pad 14, with metal bumps 24 that have contamination 18 on the metal bump surface is probed 20 during wafer testing.

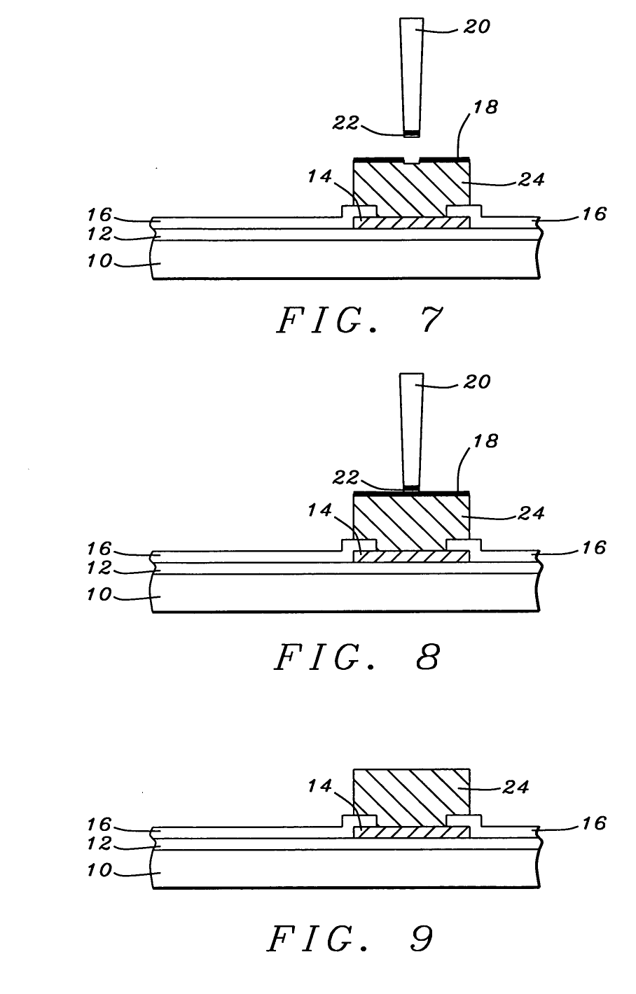

The probes 20 in FIG. 7 have picked up some of the contaminants 22 from the metal bump 24. Testing of another wafer shown in FIG. 8 allows for the contaminated probe 20, 22 to contact the metal bump 24 with contaminant 18 on its surface.

The result of the above process is that the contaminated probe contacting a contaminated metal pad provides erroneous test results such as a false open circuit indication due to the high resistance of the contaminated probe contact.

The second embodiment of the present invention addresses the problem of micro-contamination on semiconductor wafers with metal bumps by the introduction of a non-contacting physical cleaning process. The process utilizes an inert gas such as argon Ar, helium He, or neon Ne in a sputtering or ion milling process to totally remove any micro-contaminants from the metal bump surface as shown in FIG. 9. The resultant metal bumps allows for a non-resistive electrical contact during wafer testing which in turn does not produce false indication of defective product.

Although the invention has been described and illustrated with reference to specific illustrative embodiments thereof, it is not intended that the invention be limited to those illustrative embodiments. Those skilled in the art will recognize that variations and modifications can be made without departing from the spirit of the invention. It is therefore intended to include within the invention all such variations and modifications which fall within the scope of the appended claims and equivalents thereof.

1. A semiconductor fabrication and testing process comprising:
providing a semiconductor wafer having an array of any shape of exposed metal contact pads or metal bumps; and
cleaning said exposed metal contact pads or metal bumps prior to wafer probing.

2. The process of claim 1 wherein the said cleaning is accomplished by sputtering with argon Ar.

3. The process of claim 1 wherein the said process is accomplished by sputtering with helium He.

4. The process of claim 1 wherein the said process is accomplished by sputtering with neon Ne.

5. The process of claim 1 wherein the said process is accomplished by sputtering with a mixture of argon Ar helium He and neon Ne.

6. The process of claim 1 wherein the said process is accomplished by ion milling.

7. A semiconductor wafer fabrication and testing process comprising:
providing a semiconductor wafer having an array of any shape of exposed metal bumps; and
cleaning said exposed metal bumps prior to wafer probing.

8. The process of claim 7 wherein the exposed metal bumps are tin Sn.

9. The process of claim 7 wherein the exposed metal bumps are tin Sn alloy.

10. The process of claim 7 wherein said cleaning is accomplished by sputtering with argon Ar.

11. The process of claim 7 wherein said cleaning is accomplished by sputtering with helium He.

12. The process of claim 7 wherein said cleaning is accomplished by sputtering with neon Ne.

13. The process of claim 7 wherein said cleaning process is accomplished by sputtering with a mixture of argon Ar, helium He, and neon Ne.

14. The process of claim 7 wherein said cleaning is accomplished by ion milling.
